(19) United States
(12) Patent Application Publication
(10) Pub. No.: US 2021/0351323 A1
(43) Pub. Date: Nov. 11, 2021

(54) COMPONENT HAVING AN ENLARGED ACTIVE ZONE, AND PRODCUTION METHOD

(71) Applicant: OSRAM Opto Semiconductors GmbH, Regensburg (DE)

(72) Inventor: Lutz HOEPPEL, Alteglofsheim (DE)

(21) Appl. No.: 17/281,988

(22) PCT Filed: Sep. 27, 2019
(86) PCT No.: PCT/EP2019/076277

§ 371 Date: Apr. 1, 2021

(30) Foreign Application Priority Data
Oct. 2, 2018 (DE) 10 2018 124 341.3

(51) Int. Cl. H01L 33/38; H01L 33/00; H01L 33/62

(52) U.S. Cl. CPC H01L 33/382; H01L 33/005; H01L 2933/0066; H01L 2933/0016; H01L 33/62

(57) ABSTRACT

A component may have a semiconductor body, a first electrode, and a second electrode. The first electrode and the second electrode may be configured for electrically contacting a first semiconductor layer and a second semiconductor, respectively, and may have a first distribution track and a second distribution track for uniformly distributing current in the first semiconductor layer and the second semiconductor layer, respectively. The first distribution track and the second distribution track may be arranged regionally one above the other on the same side of the semiconductor body, overlap each other regionally in top view, and cover the semiconductor body only in certain places. Furthermore, the first distribution track may extend in places throughout the second semiconductor layer and the active zone to the first semiconductor layer. The active zone may be removed only in places in overlapping regions of the semiconductor body and the first distribution track.

### CROSS-REFERENCE TO RELATED APPLICATIONS

The present application is a national stage entry according to 35 U.S.C. § 371 of PCT Application No. PCT/EP2019/076277 filed on Sep. 27, 2019; which claims priority to German Patent Application Serial Nos. 10 2018 124 341.3 filed on Oct. 2, 2018; all of which are incorporated herein by reference in their entirety and for all purposes.

### TECHNICAL FIELD

A component, in particular an optoelectronic semiconductor chip for instance a light-emitting diode semiconductor chip, is provided. Furthermore, a method for producing a component, in particular a component described here, is provided.

### BACKGROUND

For an efficient operation of a component, especially of a radiation emitting component, a uniform current distribution within a semiconductor body of the component is desired. For this purpose, metallic current distribution tracks can be applied, especially in combination with transparent electrically conductive layers. However, this can lead to absorption losses, resulting in a reduction of the efficiency of the component. If the current distribution tracks are electrically conductively connected to different semiconductor layers from the same side of the semiconductor body, parts of an active zone located between the semiconductor layers are removed, resulting in a further reduction of the efficiency of the component.

One object to be solved is to specify a component, in particular a radiation-emitting semiconductor chip, having improved efficiency and low absorption losses. A further object is to specify a reliable and cost-efficient method for producing one or a plurality of high-efficiency components, in particular of components described here.

### SUMMARY

A component comprising a semiconductor body, in particular a radiation-emitting semiconductor chip, is specified. The semiconductor body has an active zone which is configured in particular for generating electromagnetic radiation such as in the ultraviolet, visible or infrared spectral range. The active zone is arranged in particular between a first semiconductor layer and a second semiconductor layer, wherein the first semiconductor layer and the second semiconductor layer are different from one another in particular with respect to their conduction type. For example, the active zone is located in a pn-junction region of the semiconductor body. In particular, the semiconductor body has a diode structure. The first semiconductor layer, the second semiconductor layer and/or the active zone can be formed in a single layer or in multiple layers.

According to at least one embodiment of the component, it has a first electrode and a second electrode. The first electrode is configured, for example, for electrically contacting the first semiconductor layer. The second electrode is configured, for example, for electrically contacting the second semiconductor layer. In particular, the first electrode and the second electrode are arranged on the same side of the semiconductor body. For example, the first electrode has an externally accessible first connection pad on an exposed surface of the component. The second electrode may have an externally accessible second connection pad on the same exposed surface of the component. The component is externally electrically connectable via the first connection pad and the second connection pad, i.e. can be electrically conductively connected to an external voltage source.

According to at least one embodiment of the component, the first electrode comprises a first distribution track, for instance a first current distribution track. The first distribution track is electrically conductively connected to the first connection pad, for example. For example, the first distribution track is regionally in indirect or direct electrical contact with the first connection pad. The first distribution track may be in direct electrical contact with the first semiconductor layer in places. In particular, the first distribution track is in electrical contact, for instance in direct electrical contact, with the first semiconductor layer in several locations. The first distribution track is configured for the lateral distribution of charge carriers that are impressed into the semiconductor body during operation of the component, in particular via the first connection pad. The first distribution track is thus configured for uniformly distributing current in the first semiconductor layer.

The first electrode may have a plurality of such first distribution tracks. For example, the first distribution tracks form a first, in particular contiguous distribution structure, for example in the form of a contact finger structure or of a contact frame structure. In a top view of the semiconductor body, the first distribution tracks, in particular all first distribution tracks, or the entire first distribution structure or the entire first electrode only partially cover/covers the semiconductor body.

According to at least one embodiment of the component, the semiconductor body has at least one opening extending along a vertical direction throughout the second semiconductor layer and the active zone towards the first semiconductor layer. In particular, the opening extends into the first semiconductor layer. The semiconductor body may have a plurality of such openings which are formed in particular isolated from each other and thus are laterally spaced from each other.

A vertical direction is understood to be a direction that is in particular perpendicular to a main extension surface of the active zone. A lateral direction is understood to be a direction that is in particular parallel to the main extension surface of the active zone. The vertical direction and the lateral direction are for instance orthogonal to each other.

The first distribution track or tracks may be arranged regionally within the opening or openings and regionally outside the opening or openings. Within the opening/s, the first distribution track may be directly adjacent to the first semiconductor layer in places. The first distribution track can partially or completely cover side walls of the opening/s.

Within the opening, the first distribution track forms a through-via of the first electrode, wherein the through-via extends along the vertical direction through the second semiconductor layer and the active zone into the first semiconductor layer. For electrically isolating the first distribution track from the second semiconductor layer and from the active zone within the opening, an insulation layer or at least a subregion of the insulation layer can be formed in the lateral direction between the semiconductor body and the first distribution track or the through-via.

Outside the opening, the first distribution track may protrude laterally beyond the opening in top view. In particular, the first distribution track is contiguous or of one-piece form. Outside the opening, the insulation layer may have a main region that is arranged in a vertical direction in places between the first distribution track and the semiconductor body. The subregion inside the opening and the main region of the insulation layer are in particular directly adjacent to each other. They may be formed of the same material or of different materials. In a top view of the semiconductor body, the first distribution track may overlap a plurality of openings. Within the respective openings, the first distribution track is in electrical contact, in particular in direct electrical contact, with the first semiconductor layer.

According to at least one embodiment of the component, the second electrode comprises a second distribution track, for instance a second current distribution track. In particular, the second distribution track is electrically conductively connected to the second connection pad. For example, the second distribution track is in direct electrical contact with the second connection pad in places. In particular, the second distribution track is electrically conductively connected to the second semiconductor layer via a connection layer and a contact layer of the second electrode. The connection layer and/or the contact layer can be formed from a radiation-transmissive electrically conductive material, for example from a transparent electrically conductive oxide, for example from ITO.

It is possible for the second distribution track to be indirectly or directly adjacent to the contact layer. The connection layer may be indirectly or directly adjacent to the second semiconductor layer. Along the vertical direction, the insulation layer, which extends regionally into the opening/s of the semiconductor body and thus covers the side walls of the opening/s, may be disposed regionally between the contact layer and the connection layer. The insulation layer can have a plurality of through-connections through which the connection layer is electrically conductively connected to the contact layer.

The second electrode may have a plurality of second distribution tracks described here. For example, the second distribution tracks form a second distribution structure, in particular a contiguous distribution structure, for instance in the form of a contact finger structure or a contact frame structure. In a top view of the semiconductor body, the second distribution tracks, for instance all second distribution tracks forming the second distribution structure, only partially cover the semiconductor body. In particular, the second distribution tracks are configured to evenly distribute current within the contact layer, the connection layer, and thus within the second semiconductor layer. The second distribution tracks can be regarded as electrically conductive conductor paths distributed on the connection layer and/or the contact layer and, in particular, configured for uniformly laterally distributing the current within the contact layer. The first distribution tracks can also be regarded as electrically conductive conductor tracks which make electrical contact with the first semiconductor layer at a plurality of locations.

In a non-limiting embodiment, the second distribution track or the plurality of second distribution tracks is formed of a material whose electrical resistance is lower than an electrical resistance of the material of the connection layer and/or of the contact layer. In this sense, the second distribution track or the plurality of second distribution tracks is configured for laterally distributing charge carriers which are impressed into the semiconductor body during operation of the component, in particular via the second connection pad. It is possible that the second electrode comprising the second distribution tracks, the second connection pad, the connection layer and/or the contact layer completely covers or almost completely covers the semiconductor body in top view, for example up to 80%, 90%, 95% or 99% of a main surface of the semiconductor body or of a surface of the second semiconductor layer.

According to at least one embodiment of the component, the first distribution track and the second distribution track are arranged at least in places one above the other on the same side of the semiconductor body, wherein the first distribution track and the second distribution track overlap each other in a plan view of the semiconductor body. In particular, the first distribution track and the second distribution track are located in their overlapping region or regions on different vertical planes of the component. In top view, the first distribution track is disposed along the vertical direction for instance between the semiconductor body and the second distribution track. The first distribution track and the second distribution track may each be formed from a radiation non-transmissive material, for instance from a metal, in particular from the same metal.

In at least one embodiment, the component comprises a semiconductor body, a first electrode, and a second electrode, wherein the semiconductor body comprises a first semiconductor layer, a second semiconductor layer and an active zone located therebetween. The first electrode is configured for electrically contacting the first semiconductor layer and has a first distribution track for uniformly distributing current in the first semiconductor layer. The second electrode is configured for electrically contacting the second semiconductor layer and has a second distribution track for uniformly distributing current in the second semiconductor layer. The first distribution track and the second distribution track are arranged at least regionally one above the other on the same side of the semiconductor body, overlap each other in top view and cover the semiconductor body only in places. In a non-limiting embodiment, the first distribution track extends in places throughout the second semiconductor layer and the active zone towards the first semiconductor layer, wherein the active zone is removed only in places in the regions of the semiconductor body overlapping with the first distribution track.

According to at least one embodiment of the component, it has a substrate on which the semiconductor body is grown. The first electrode and the second electrode are arranged in particular one above the other on the same main surface of the semiconductor body facing away from the substrate. For example, the substrate is a growth substrate on which the semiconductor body is epitaxially grown. In particular, the substrate is a sapphire substrate.

According to at least one embodiment of the component, the component has a front side facing away from the substrate, which is formed in particular as a radiation exit surface of the component. The first electrode and/or the second electrode are/is formed on the front side of the component. It is possible that the component has several radiation exit surfaces. For example, the component is formed as a volume emitter. In the case of a volume emitter, the electromagnetic radiation generated during operation of the component can be coupled out of the component not only via the front side of the component, but in particular also via side surfaces of the component and/or via a rear side of the component. In particular, the electromagnetic radiation generated during operation of the component can be coupled out of the component in all spatial directions. The rear side of the component may be formed by a surface of the substrate. The substrate may be formed to be transmissive to electromagnetic radiation generated during operation of the component.

According to at least one embodiment of the component, the semiconductor body has at least one opening extending throughout the second semiconductor layer and the active zone into the semiconductor layer. In particular, the first distribution track forms a through-via of the first electrode within the opening. The sidewalls of the opening may be covered by a subregion of the insulation layer. In a non-limiting embodiment, a lateral distance between the through-via and the semiconductor body is given exactly by a single layer thickness of the subregion of the insulation layer.

According to at least one embodiment of the component, the side walls of the opening form an angle of 90°±30°, for instance 90°±20°, 90°±10° or 90°±5°, with respect to a main plane of extension of the active zone. The opening has a cross-section that in particular increases with increasing vertical distance from a bottom surface of the opening. The bottom surface of the opening may be a surface of the first semiconductor layer exposed in the opening.

According to at least one embodiment of the component, the first distribution track and the second distribution track overlap in top view both inside the opening and outside the opening. In a top view of the semiconductor body, the second distribution track may at least partially cover the opening or the openings of the semiconductor body. It is possible for the second distribution track to extend regionally into the opening or into a plurality of openings. The second distribution track may be arranged regionally outside the opening/s and regionally inside the opening/s.

According to at least one embodiment of the component, the first distribution track is formed to be radiation-reflective, in particular reflective with regard to the radiation generated during operation of the component. The first distribution track extends along a vertical direction, in particular from the bottom surface of the opening via the side walls to a surface of the main region of the insulation layer facing away from the semiconductor body. In a top view of the semiconductor body, the first distribution track may protrude laterally beyond the opening/s.

The semiconductor body may have a plurality of openings described here, for instance with the through-vias formed therein, with the insulation layer formed therein, and/or with the first and/or second distribution tracks disposed therein.

According to at least one embodiment of the component, the semiconductor body has a plurality of laterally spaced openings, wherein each of which extends through the second semiconductor layer and the active zone to the first semiconductor layer, and wherein the first distribution track and/or the second distribution track are/is formed contiguously and are/is arranged regionally inside the openings and regionally outside the openings. Inside the openings, the active zone is in particular not present. For example, when forming the openings, the active zone is removed in the regions of the openings to expose the first semiconductor layer. In the lateral intermediate regions between the openings, the active zone is still present. Even in the presence of the opening or openings, the entire active zone of the semiconductor body may be formed contiguously. In other words, the active zone may be free of a subregion that is spatially cut off from the rest of the active zone and thus isolated.

If the first distribution track or the second distribution track is arranged regionally inside the opening/s and regionally outside the opening/s, it can have regions overlapping with the semiconductor body, wherein the active zone is only removed in places, is not removed or is completely removed. In particular, the active zone is removed only in the regions of the semiconductor body overlapping with the openings. In the overlapping regions outside the opening/s, the semiconductor body may still be configured to generate electromagnetic radiation. Compared to the case of the first distribution track and/or the second distribution track being arranged exclusively or almost exclusively inside the opening/s of the semiconductor body with the same coverage area, and thus a larger portion of the active zone being removed, the efficiency of the component may be increased since the distribution tracks are formed regionally inside and regionally outside and the opening/s the component thus has a larger active zone.

According to at least one embodiment of the component, the first distribution track has, in top view, an outer length portion outside the opening/s and an inner length portion inside the opening/s. The outer length portion may be greater than the inner length portion, or vice versa. For example, a ratio between the inner and outer length portions may be between 0.05 and 20 inclusive, between 0.1 and 10 inclusive, for example between 0.2 and 8 inclusive, or between 0.25 and 4 inclusive. The component may have, in top view, an outer total length portion and an inner total length portion of all the first distribution tracks, wherein a ratio between the inner and outer total length portions may be between 0.05 and 20 inclusive, between 0.1 and 10 inclusive, for example between 0.2 and 8 inclusive, or between 0.25 and 4 inclusive. The outer total length fraction may be greater than the inner total length fraction, or vice versa.

According to at least one embodiment of the component, the first electrode has a first freely accessible connection pad that is electrically conductively connected to the first distribution track. The second electrode has a second freely accessible connection pad that is electrically conductively connected to the second distribution track. In particular, the first connection pad and the second connection pad are located on the semiconductor body and, in top view, have overlapping regions with the semiconductor body. In a non-limiting embodiment, the active zone in the regions of the semiconductor body overlapping with the first connection pad and/or with the second connection pad is at least partially not removed. In other words, all or part of the active zone is present in the overlapping regions between the semiconductor body and the first and/or second connection pad.

The first connection pad and the second connection pad are in particular free of overlap in top view. It is possible that in a top view of the semiconductor body, the first connection pad and/or the second connection pad are/is formed completely outside, for example laterally, of the opening/openings of the semiconductor body. In this case, the first and/or second connection pad are/is free of overlaps with the openings of the semiconductor body.

Furthermore, it is possible that the first connection pad or the second connection pad at least partially covers the opening/s and/or the first distribution track in top view. Generally, the connection pads are formed of a metal and are thus opaque to radiation. If the first connection pad or the second connection pad covers the opening/s of the semiconductor body, where the active zone is removed, or the first distribution track, which—with regard to its conductivity—is formed from a metal and is thus opaque to radiation, the overall shading area of the component may be reduced. Alternatively, it is possible that the first connection pad and/or the second connection pad are/is arranged within a respective opening of the semiconductor body. In this case, the semiconductor body has regions overlapping with the first and/or second connection pad, where the active zone is partially or completely removed.

According to at least one embodiment of the component, the first electrode has a plurality of strip-shaped first distribution tracks. The distribution tracks are in particular formed from a metal. The first distribution tracks cover, in top view, at most 15%, 10%, 5% or at most 3% of a lateral main surface of the semiconductor body, for instance between 1% and 10% inclusive or between 1% and 5% inclusive. The second electrode may include a plurality of strip-shaped second distribution tracks for instance formed from a metal. The first and second distribution tracks may be formed from the same metal or from different metals. In particular, the second distribution tracks cover, in top view, at most 15%, 10%, 5% or at most 3% of the main lateral area of the semiconductor body, for instance between 1% and 10% inclusive or between 1% and 5% inclusive. It is possible that the first and second distribution tracks cover, in top view, at most 25%, 20%, 15%, 10% or at most 5% of the main lateral area of the semiconductor body, for instance between 1% and 15% inclusive, between 1% and 10% inclusive or between 1% and 5% inclusive.

A distribution track is strip-shaped if, in top view of the semiconductor body, it has a longitudinal length and a transverse width, wherein a ratio of the length to the width is, for example, at least 3, 5, 10 or at least 20. For example, the ratio of the length to the width of the distribution track is between 3 and 300 inclusive, between 3 and 200 inclusive, between 3 and 100 inclusive, or between 3 and 50 inclusive.

The distribution tracks, in particular the strip-shaped distribution tracks, can be directly adjacent to one another and form a common distribution structure, which is frame-shaped, branched, finger-structure-like or can have other forms. The common distribution structure comprising the distribution tracks is electrically conductively connected to an associated connection pad, for example, and can be of contiguous or one-piece design.

According to at least one embodiment of the component, the first distribution tracks, in particular all first distribution tracks, form a first distribution structure. The second distribution tracks, in particular all second distribution tracks, form a second distribution structure. The second distribution structure is arranged at least in places on or above the first distribution structure. The first distribution structure is arranged in the vertical direction for instance between the second distribution structure and the semiconductor body.

In a top view of the semiconductor body, the first distribution structure and the second distribution structure overlap at least in places. Regions, where the first distribution structure and the second distribution structure overlap, are configured both for lateral distribution of current when the first semiconductor layer is connected and for lateral distribution of current when the second semiconductor layer is connected. For example, in a top view of the semiconductor body, at least 10%, 30%, 50%, 70%, or at least 90% of the first distribution structure is located within the second distribution structure, or vice versa.

Compared to a component, according to which the first distribution structure and the second distribution structure are arranged next to each other without being overlapped in top view, the area of the active zone covered by the distribution tracks may be reduced.

According to at least one embodiment of the component, the second electrode comprises a plurality of radiation non-transmissive strip-shaped second distribution tracks, a radiation non-transmissive connection pad, a radiation non-transmissive connection layer and a radiation non-transmissive contact layer. In top view, the entire second electrode may completely cover the active zone or the semiconductor body.

The connection layer and the contact layer are formed from a transparent electrically conductive material. The second distribution tracks are electrically conductively connected to the connection layer, for example via the contact layer. The connection layer is in particular directly adjacent to the second semiconductor layer. In top view, the connection layer and/or the contact layer can completely or almost completely cover the semiconductor body or the active zone, for example up to 70%, 80%, 90%, 95% or 99% of a main region of the semiconductor body or the active zone.

According to at least one embodiment of the component, it is formed as a radiation-emitting semiconductor chip. The active zone is configured to generate electromagnetic radiation when the component is in operation. The first electrode is formed to be transmissive to the generated radiation and, in top view, covers the active zone in particular only partially. The second electrode is formed to be opaque to the generated radiation in places and to be transmissive to the generated radiation in places. In top view, the entire second electrode may completely cover the active zone. The first electrode may have a plurality of radiation non-transmissive strip-shaped first distribution tracks and a radiation non-transmissive connection pad, wherein the first electrode, in top view, only partially covers the active zone and/or the semiconductor body.

A method for producing a component is specified, whose semiconductor body has one opening or several openings for electrically contacting a first semiconductor layer of the semiconductor body, wherein an insulation layer is formed regionally inside and regionally outside the opening/s. The method described here is particularly suitable for the production of a component described here. The features described in connection with the component can therefore also be used for the method, and vice versa.

According to at least one embodiment of the method, in a first photo layer, the active zone is not removed in the entire areas of the semiconductor body provided for the first and/or second distribution tracks. In order to expose connection areas, in particular n-side connection areas, for electrically contacting the first semiconductor layer, a plurality of laterally spaced openings are formed, in particular throughout the second semiconductor layer and the active zone, to the first semiconductor layer. This is performed in particular by the so-called mesa etching.

The passivation of the bottom surfaces and of the side walls of the opening/s or of mesa trenches and of the exposed active zone is carried out by the formation of the insulation layer, in particular without a separate photographic technique. As a result, there is no need for further area reservation in the lateral directions between the through-via formed in an opening and the semiconductor body or between the through-via and the side walls of the opening in question.

In at least one embodiment of the method, the insulation layer is formed, in top view, from a main region outside the opening and from a subregion at least partially or exclusively inside the opening. In particular, the main region is directly adjacent to the subregion, for instance at an edge or edges of the opening. In a non-limiting embodiment, the main region is formed in a separate process step prior to the subregion. The main region and the subregion can be formed from the same material, for instance from SiO2, or from different materials.

According to at least one embodiment of the method, the main region is formed prior to the formation of the opening by applying a first passivation layer in particular to the radiation-transmissive electrically conductive connection layer of the second electrode. The subregion may be formed after the formation of the opening by applying a second passivation layer to surfaces of the opening, wherein the second passivation layer runs conformally to side walls and a bottom surface of the opening.

The second passivation layer can initially completely cover the bottom surface and/or the side walls of the opening. To expose the bottom surface of the opening, the second passivation layer is removed in places, wherein the remaining second passivation layer on the side walls of the opening forms, in particular, the subregion of the insulation layer inside the opening. In a non-limiting embodiment, the second passivation layer is removed in places to expose the bottom surface of the opening by an anisotropic and/or maskless etching process. The formation of the first and/or of the second passivation layer or the formation of the main region and/or the subregion of the insulation layer can be carried out without the application of a photo technique and in particular without an additional photo layer.

Before the insulation layer is formed, the connection layer, which is made in particular from a transparent conductive material, can be applied over the surface of the second semiconductor layer. The connection layer serves in particular for electrically contacting, for example for p-side electrically contacting the second semiconductor layer. The connection layer has a vertical layer thickness which can be a few nanometers, for example around 10 nm or 20 nm, for example between 3 nm and 30 nm inclusive. It is possible that the deposition of the connection layer on the second semiconductor layer takes place prior to the mesa etching for the forming the opening/s.

After passivation, for example by using the first passivation layer, and mesa etching, and in particular after a renewed passivation by the second passivation layer, an etching process, in particular a maskless etching process, can be carried out in a targeted manner in such a way that the contact surfaces of the first semiconductor layer, for instance the bottom surfaces of the openings, which are provided for electrical contacting purposes, are again free of the insulation layer, in particular free of the second passivation layer, while the side walls of the opening/s continue to be covered or encapsulated by the second passivation layer, and the connection layer continues to be covered or encapsulated by the first passivation layer and possibly additionally by the second passivation layer.

The subregion of the insulation layer within the opening, which is formed by the remaining second passivation layer, serves in particular as a so-called lateral “spacer” between the semiconductor body and the through-via. Within the opening, the entire subregion of the insulation layer runs in particular parallel to the side wall covered by the subregion or to the side walls of the opening. Outside the opening/s, the second passivation layer may be completely removed. The first passivation layer, which forms the main region of the insulation layer outside the opening/s, can partially act as a sacrificial layer for the etching process for forming the spacer.

The first and/or the second distribution tracks may be formed regionally inside and regionally outside the opening/s, wherein the active zone is removed only inside the opening/s. Outside the opening/s, the component can have regions of the semiconductor body overlapping with the distribution tracks wherein the active zone is present, i.e. not removed. Overall, this results in more active area provided for generating electromagnetic radiation, especially compared to the case where the distribution tracks, especially the first distribution tracks, are arranged exclusively or predominantly within a large or wide opening of the semiconductor body.

In particular, the first distribution track or the plurality of first distribution tracks is located on different vertical levels of the component, for example on a lateral level directly on the bottom surface or on the bottom surfaces of the opening/s, on side walls of the opening/s and on a lateral level above the connection layer, for example directly on a surface of the insulation layer facing away from the semiconductor body. The first distribution track or the plurality of the first distribution tracks may smoothly cover the edges of the opening/s. Due to the smooth covering and self-alignment of the insulation layer and/or of the distribution tracks at the edges of the opening/s, there is practically no additional surface reservation between the side walls of the opening and the subregion of the first distribution track formed as a through-via, which unnecessarily enlarges the opening/s. As a result, the component effectively has more active area for generating electromagnetic radiation.

According to at least one embodiment of the method, in top view of the semiconductor body, a first connection pad and/or a second connection pad are/is formed sidewards from the opening/s. Such connection pads are in particular freely accessible and are provided for electrically contacting the component with an external voltage source. The connection pads may each have a diameter of around 80 micrometers, for instance between 50 micrometers and 150 micrometers inclusive. In particular, the active zone in the overlapping regions with the connection pads is not removed and can still be energized to generate light, thereby increasing the internal quantum efficiency of the component. Furthermore, the installation of such connection pads, in particular outside the opening/s, does not require an additional mask layer.

According to at least one embodiment of the method, the first distribution track or a plurality of first distribution tracks is formed inside and outside the opening/s. Inside the opening/s, the first distribution track can replicate a contour of the opening and, in particular, does not completely fill the opening along the vertical direction. In other words, the first distribution track runs conformally to the bottom surface and to the side walls of the opening. The subregion of the first distribution track located in the opening forms a through-via of the first electrode. In particular, the through-via is directly adjacent to the first semiconductor layer. A lateral distance between the through-via and the semiconductor body is given in particular exactly by a single layer thickness of the subregion of the insulation layer within the opening, i.e. by a single lateral layer thickness of the spacer.

### BRIEF DESCRIPTION OF THE DRAWINGS

Further embodiments and further developments of the component or the method will be apparent from the embodiments explained below in connection with FIGS. 1A to 3E and 4A to 4E.

FIGS. 1A, 1B, 1C and 1D show schematic illustrations of a comparative example of a component in top view or in vertical sectional view.

FIG. 2A shows a schematic illustration of an exemplary embodiment of a component in top view.

FIGS. 2B, 2C, 2D and 2E show schematic illustrations of various sections of an exemplary embodiment of a component, each in a vertical sectional view.

FIG. 3A shows a schematic illustration of a further exemplary embodiment of a component in top view.

FIGS. 3B and 3C show schematic illustrations of various sections of a further exemplary embodiment of a component, each in a vertical sectional view.

FIGS. 3D and 3E show schematic illustrations of further exemplary embodiments of a component in top view.

FIGS. 4A to 4E show schematic illustrations of some process steps for producing one or a plurality of components.

Identical, equivalent or equivalently acting elements are indicated with the same reference numerals in the figures. The figures are schematic illustrations and thus not necessarily true to scale. Comparatively small elements and particularly layer thicknesses can rather be illustrated exaggeratedly large for the purpose of better clarification.

### DETAILED DESCRIPTION

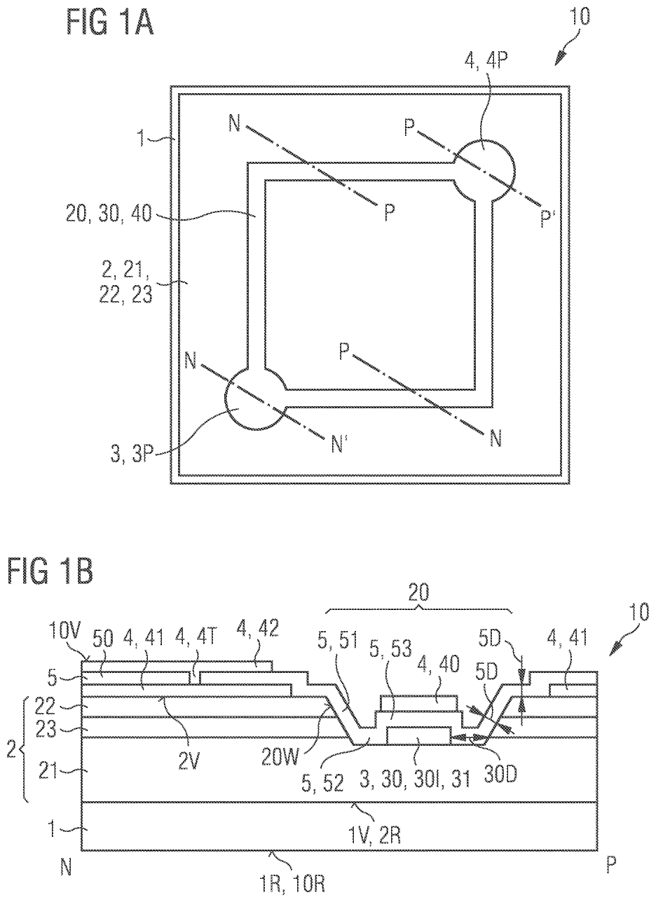

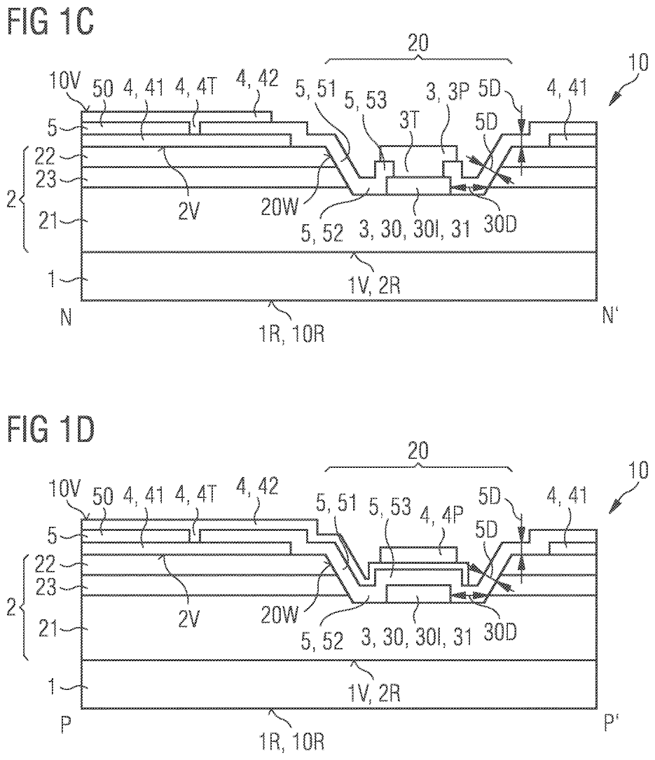

FIG. 1A shows a comparative example of a component 10 in top view of its semiconductor body 2. FIGS. 1B, 1C and 1D show sections of the component 10 along the sectional planes NP, NN′ and PP′ shown in FIG. 1A, respectively, in vertical sectional view.

The semiconductor body 2 is arranged on a substrate 1 and may include a first semiconductor layer 21, a second semiconductor layer 22 and an active zone 23, wherein the active zone 23 is arranged in the vertical direction between the first semiconductor layer 21 and the second semiconductor layer 22. The first semiconductor layer 21 is disposed in the vertical direction between the substrate 1 and the active zone 23. In particular, the first semiconductor layer 21 is n-type. The second semiconductor layer 22 may be of p-type. For example, the substrate 1 is a growth substrate on which the semiconductor body is epitaxially grown.

The semiconductor body 2 may be formed of a III/V or II/VI compound semiconductor material. A III/V compound semiconductor material has an element from the third main group and an element from the fifth main group. A II/VI compound semiconductor material has an element from the second main group and an element from the sixth main group. In particular, the semiconductor body 2 is based on GaN and is grown on a sapphire substrate 1.

The semiconductor body 2 has a front-side main surface 2V facing away from the substrate 1 and a rear-side main surface 2R facing the substrate 1. In particular, the rear-side main surface 2R is formed by a surface of the first semiconductor layer 21 which for instance is directly adjacent to a front side 1V of the substrate 1. The substrate 1 has a rear side 1R facing away from the front side 1V, which in particular forms a rear side 10R of the component 10. The component has a front side 10V facing away from the rear side 10R. In particular, the front side 10V and the rear side 10R delimit the component 10 along vertical directions. In operation of the component 10, generated radiation may be coupled out of the component 10 at the front side 10V. If the substrate 1 is formed to be radiation-transmissive, it is possible for electromagnetic radiation to be coupled out from the component 10 at the rear side 10R. The front side 10V and/or the rear side 10R may be formed as radiation exit surface/s of the component 10.

The semiconductor body 2 has an opening 20 which extends at least in places from the front-side main surface 2V through the second semiconductor layer 22 and the active zone 23 into the first semiconductor layer 21. Within the opening 20, the active zone 23 is removed, in particular completely removed (FIG. 1B). In top view, the opening 20 may be contiguous and for instance frame-shaped (FIG. 1A). In particular, the opening 20 is configured to receive a first electrode 3 and/or a second electrode 4 of the component 10.

Within the opening 20, the first electrode 3 and the second electrode 4 are arranged in particular one above the other along the vertical direction. For electrical insulation, an insulation layer 5, in particular a main region 50 of the insulation layer, can be arranged in the vertical direction in places between the first electrode 3 and the second electrode 4. Expediently, the insulation layer 5 is formed from an electrically insulating material, for instance from silicon oxide, for example from SiO2. The first electrode 3 may be configured for electrically contacting the first semiconductor layer 21. The second electrode 4 is configured in particular for electrically contacting the second semiconductor layer 22.

The first electrode 3 may have at least a first distribution track 30 that is electrically conductively connected to a connection pad 3P of the first electrode 3. The first connection pad 3P is located for instance in a region of the opening 20 with an enlarged diameter. The first distribution track 30 is in electrical contact with the first semiconductor layer 21, in particular in direct electrical contact. The first electrode 3 may have a plurality of such first distribution tracks 30. The first distribution track 30 or the plurality of first distribution tracks 30 serves, in particular, for making electrical contact and laterally spreading the current within the first semiconductor layer 21.

The second electrode 4 can have at least one second distribution track 40, which is electrically conductively connected to a connection pad 4P, in particular directly connected to a connection pad 4P of the second electrode 4. The connection pad 4P is located for instance in a further region of the opening 20 having an enlarged diameter. In other words, the connection pad 3P or 4P is located in an area of the opening, which—compared to the areas where the first and/or second distribution track 30 and/or 40 are/is arranged—has an enlarged diameter or an enlarged local expansion. The component 10 can be externally electrically contacted via the connection pads 3P and 4P, which are assigned to the different electrical polarities of the component 10. In a non-limiting embodiment, the connection pads 3P and 4P are accessible from the outside. The connection pads 3P and 4P may each be configured as a bond pad surface, for instance as a wire-bonding surface.

The second distribution track 40 is electrically conductively connected to the second semiconductor layer 22 for instance via a connection layer 41 and a contact layer 42 (see FIGS. 1B and 1D). The second distribution track 40 may be in direct electrical contact with the contact layer 42 in places. The insulation layer 5 is arranged in the vertical direction between the contact layer 42 and the connection layer 41 in places, wherein the contact layer 42 are electrically conductively connected to the connection layer 41 via a through-contact 4T or via a plurality of through-contacts 4T. The through-contact 4T or the plurality of through-contacts 4T extend through the main region 50 of the insulation layer 5. In particular, the through-contacts 4T are formed with respect to their density and cross-sections in such a way that a uniform current impressing from the contact layer 42 into the connection layer 41 is achievable. The contact layer 42 and the connection layer 41 thus serve as current spreading layers of the second electrode 4, wherein the second distribution track/s 40 is/are configured for lateral current spreading within the contact layer 42.

The second electrode 4 may have a plurality of such second distribution tracks 40. The second distribution track 40 or the plurality of second distribution tracks 40 serves in particular for making electrical contact and lateral current spreading within the contact layer 42, the connection layer 41 and thus within the second semiconductor layer 22, which in particular is directly adjacent to the connection layer 41.

The contact layer 42 and/or the connection layer 41 may be formed from a material having a lower electrical conductivity than a material of the second distribution track 40, for instance from a radiation-transmissive and electrically conductive material. In top view, the contact layer 42 and/or the connection layer 41 may cover a larger portion of the main surface 2V of the semiconductor body 2 or of the second semiconductor layer 22 than the second distribution track 40 or the entire distribution tracks 40.

According to the comparative example illustrated in FIGS. 1A, 1B, 1C, and 1D, the first connection pad 3P, the second connection pad 4P, the first distribution track 30, the second distribution track 40, and/or the plurality of distribution tracks 30 and 40 are/is located at least partially or exclusively within the opening 20. The opening 20 should therefore be large and wide enough to accommodate the first connection pad 3P, the second connection pad 4P, the first distribution track 30, the second distribution track 40, and/or the plurality of distribution tracks 30 and 40. However, this results in a large amount of active area of the component 10 being lost due to the absence of the active zone 23 within the opening 20.

In FIG. 1B, the first electrode 3 comprising the first distribution track 30, the second electrode 4 having the second distribution track 40 and the insulation layer 5 in the area of the opening 20 are shown in more detail.

The first distribution track 30 or the plurality of first distribution tracks 30 is arranged in top view in particular exclusively within the opening 20 and thus has only an inner subregion 30I, which is formed in particular as a connection layer 31 of the first electrode. The connection layer 31 or the first distribution track 30 in particular directly adjoins the first semiconductor layer 21 at any places. The second distribution track 40 or the plurality of second distribution tracks 40 may be arranged exclusively within the opening 20 in top view. The first distribution track 30 and the second distribution track 40 are thus arranged one above the other and have overlapping regions.

Outside the opening 20, the insulation layer 5 has a main region 50, which is arranged in particular between the connection layer 41 and the contact layer 42. Inside the opening 20, the insulation layer 5 has a first subregion 51, a second subregion 52 and a third subregion 53. The first subregion 51 covers side walls 20W of the openings 20, in particular completely. The third subregion 53 is arranged between the first distribution track 30 and the second distribution track 40 and is provided for electrically insulating the first distribution track 30 from the second distribution track 40. The second subregion 52 extends along the lateral direction between the first subregion 51 and the third subregion 53. A lateral distance 30D between the semiconductor body 2 and the first distribution track 30 and/or the second distribution track 40 is, in particular, a multiple of a single layer thickness 5D of the insulation layer 5. Due to the presence of the second subregion 52, the active zone 23 is removed in this region. It is therefore desirable that the second subregion 52 of the insulation layer 5 be kept as small as possible.

The section shown in FIG. 1C is substantially the same as the section of a component 10 shown in FIG. 1B. In contrast, the section NN′ is located in the area of the first connection pad 3P. The connection pad 3P may be arranged within the opening 20, in particular completely within the opening 20, on the insulation layer 5 and on the first distribution track 30. The first connection pad 3P is electrically conductively connected to the first distribution track 30 by a through-contact 3T of the first electrode 3 extending throughout the insulation layer 5, in particular throughout the third subregion 53 of the insulation layer 5. According to FIG. 1C, the active zone 23 is not present in a region of the semiconductor body 2 overlapping with the first connection pad 3P.

The section shown in FIG. 1D is substantially the same as the section of a component 10 shown in FIG. 1B. In contrast, the section PP′ is located in the region of the second connection pad 4P.

The connection pad 4P can be arranged within the opening 20, in particular completely within the opening 20, on the contact layer 42, on the insulation layer 5 and on the first distribution track 30. In particular, the connection layer 41 is not present in the region of the opening 20 or in the regions of the openings 20 in top view. The contact layer 42 may extend into the opening 20 in places. In the vertical direction, the contact layer 42 is arranged for instance between the second connection pad 4P and the insulation layer 5 or the third subregion 53 of the insulation layer 5. The second connection pad 4P is arranged above the first distribution track 30 and has an overlapping region with the first distribution track 30. Referring to FIG. 1D, the active zone 23 is not present in a region of the semiconductor body 2 overlapping with the second connection pad 4P.

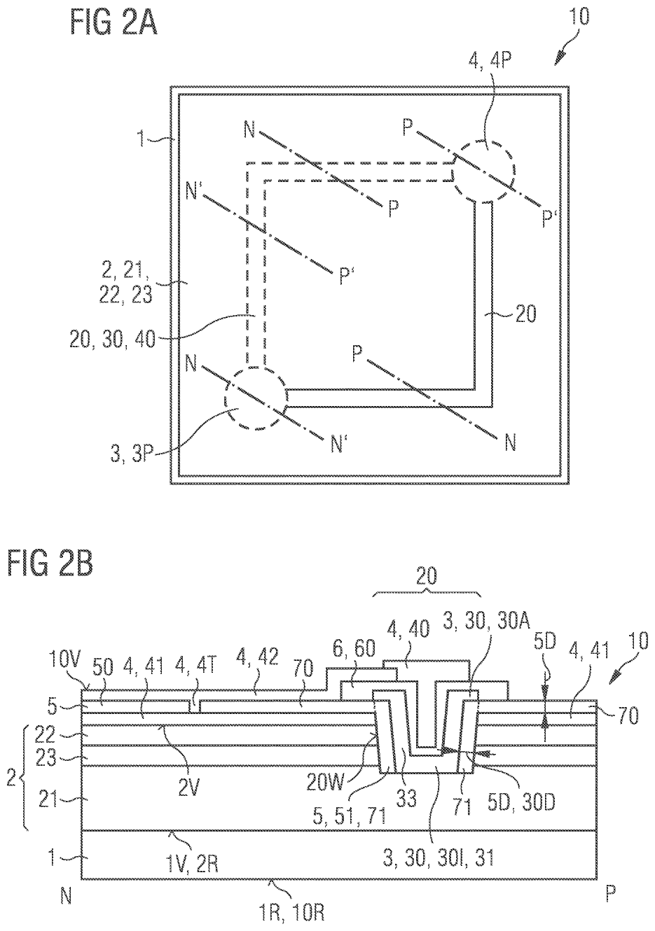

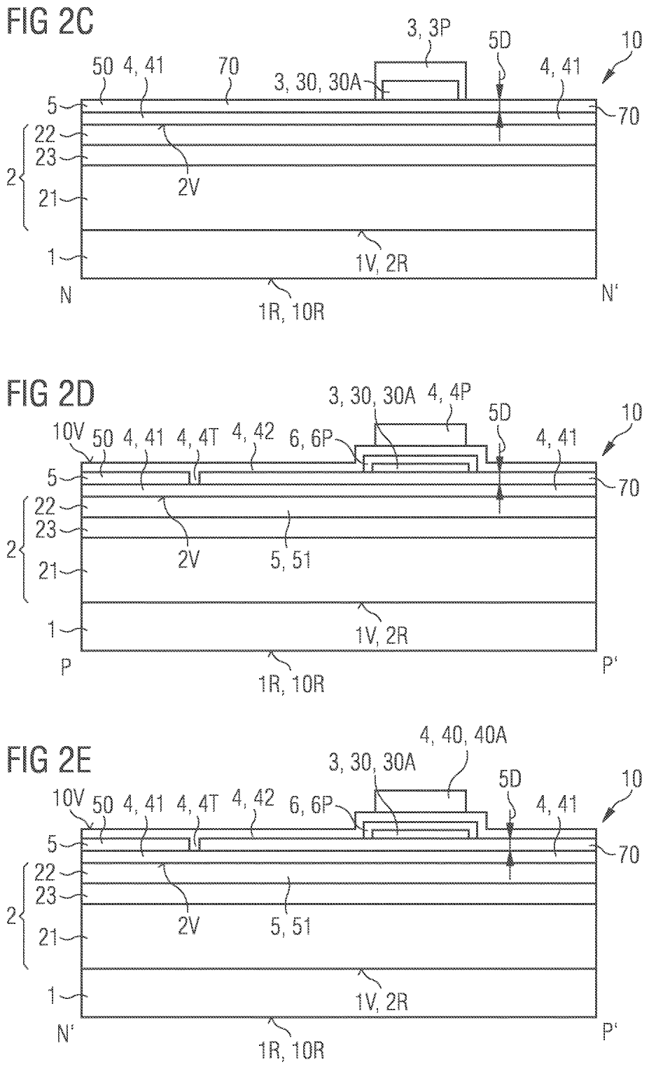

The exemplary embodiment shown in FIG. 2A is substantially the same as the exemplary embodiment of a component 10 shown in FIG. 1A, except that the first connection pad 3P and/or the second connection pad 4P are/is arranged outside the opening 20 or openings 20 in top view. Referring to FIG. 2A, the active zone 23 is present in the regions of the semiconductor body 2 overlapping with the first connection pad 3P and/or the second connection pad 4P (see FIGS. 2C and 2D).

In further contrast to FIG. 1A, the component 10 of FIG. 2A has a plurality of laterally spaced openings 20. Together, the openings 20 may be arranged in a frame-like, branched, or finger-structure-like manner. Compared to FIG. 1A, the sum of all cross-sections of the openings 20 shown in FIG. 2A may be smaller than the cross-section of the opening 20 shown in FIG. 1A. The first distribution track 30, the plurality of first distribution tracks 30, the second distribution track 40, and/or the plurality of second distribution tracks 40 may be disposed regionally inside and regionally outside the opening/s 20. Outside the opening/s 20, the semiconductor body 2 may have regions overlapping with the first distribution track 30 and/or with the second distribution track 40, where the active zone 23 is present, i.e., not removed (see FIGS. 2C, 2D and 2E).

FIGS. 2B, 2C, 2D, and 2E show sections of the component 10 along various sectional planes NP, N′P′, NN′, and PP′ shown in FIG. 2A in vertical sectional view, respectively.

The section shown in FIG. 2B is substantially the same as the section of a component 10 shown in FIG. 1B. In contrast, the first distribution track 30 has an inner subregion 30I inside the opening 20 and an outer subregion 30A outside the opening 20. The inner subregion 30I includes a connection layer 31, which is in particular directly adjacent to the first semiconductor layer 21, and a through-via 33 connecting the connection layer 31 to the outer subregion 30A. The through-via 33 surrounds the connection layer 31 in lateral directions. In this sense, the connection layer 31 may be regarded as part of the through-via 33.

The first distribution track 30 only partially fills the opening 20 and replicates a contour of the opening 20. In particular, the lateral distance 30D between the first distribution track 30 and the semiconductor body 2 or between the through-via 33 and the semiconductor body 2 is given by a single layer thickness 5D of the insulation layer 5 within the opening 20, i.e. by a single layer thickness 5D of a subregion 51 or of a spacer 51 of the insulation layer 5. Compared to FIG. 1B, the insulation layer 5 within the opening 20 has only a first subregion 51 covering the side walls 20W of the opening 20. In particular, the insulation layer 5 is free of a second subregion 52 and/or a third subregion 53 for instance as shown in FIG. 1B.

Outside the opening/s 20, the insulation layer 5 has a main region 50. In particular, the main region 50 is directly adjacent to the subregion 51, for example at an edge of the opening 20, or to the subregions 51, for example at several edges of the openings 20. For example, the main region 50 is formed by a first passivation layer 70. The subregion 51 or subregions 51 may be formed by a second passivation layer 71. In particular, the main region 50 and the subregion 51 adjacent to the main region 50 are formed as different sublayers of the insulation layer 5. A boundary line or interface between these sublayers is shown by dashed line in FIG. 2B. Compared to FIG. 1B, in FIG. 2B, the side walls 20W of the opening 20 form a steeper angle with a main plane of extension of the active zone 23, namely an angle of about 90°±30°. Thus, a reduced cross-section of the opening 20 can be obtained, as a result of which less active area of the active zone 23 is removed.

As a further difference to FIG. 1B, the second distribution track 40 according to FIG. 2B is arranged partly inside and laterally as well as vertically outside the opening 20. In places, the second distribution track 40 may extend into the opening 20. The second distribution track 40 may be directly adjacent to the contact layer 42. The component 10 has a separation layer 6, which is formed in particular to be electrically insulating and is arranged in places inside the opening 20 and in places outside the opening 20.

For example, the separation layer 6 has a first sublayer 60 disposed between the first distribution track 30 and the second distribution track 40. The separation layer 6 may be directly adjacent to the insulation layer 5 in places. The separation layer 6 and the insulation layer 5 may be formed of the same material or of different materials. In particular, the separation layer 6 and the insulation layer 5 are formed in different process steps so that an interface between the separation layer 6 and the insulation layer 5 is apparent. The opening 20 may be completely filled by the insulation layer 5, the separation layer 6, the first distribution track 30 and the second distribution track 40.

The section shown in FIG. 2C is substantially the same as the section of a component 10 shown in FIG. 1C, except that no opening/s 20 is formed in the section NN′ comprising the first connection pad 3P. Therefore, the first connection pad 3P is located outside the opening/s 20. Outside the opening/s 20, the first distribution track 30 and/or the first connection pad 3P are/is arranged on the insulation layer 5 and the connection layer 41. In particular, the first distribution track 30 and/or the first connection pad 3P are/is located completely above the semiconductor body 2, for instance above the front-side main surface 2V of the semiconductor body 2.

The section shown in FIG. 2D is substantially the same as the section of a component 10 shown in FIG. 1D. In contrast, in the section PP′ showing the second connection pad 4P, an opening 20 is not formed. The second connection pad 4P is located outside the opening/s 20. Outside the opening/s 20, the first distribution track 30 and/or the second connection pad 4P are/is arranged on the insulation layer 5 and the connection layer 41, in particular completely above the semiconductor body 2, for instance above the front-side main surface 2V of the semiconductor body 2.

The second connection pad 4P and the contact layer 42 are disposed above the first distribution track 30 and have overlapping regions therewith. The separation layer 6 has a second sub-layer 6P that, in top view, encapsulates the first distribution track and electrically isolates it from the contact layer 42 and/or from the second distribution track 40 or from the second connection pad 4P. The first sub-layer 60 and the second sub-layer 6P may be laterally spaced from each other. In a top view of the second connection pad 4P, the active zone 23 is not removed in the overlapping regions and is therefore present.

The section shown in FIG. 2E is substantially the same as the section of a component 10 shown in FIG. 2D. In contrast, section N′P′ does not include a second connection pad 4P but instead includes the second distribution track 40. Moreover, the section N′P′ shown in FIG. 2E may be identical to the section PP′ shown in FIG. 2D.

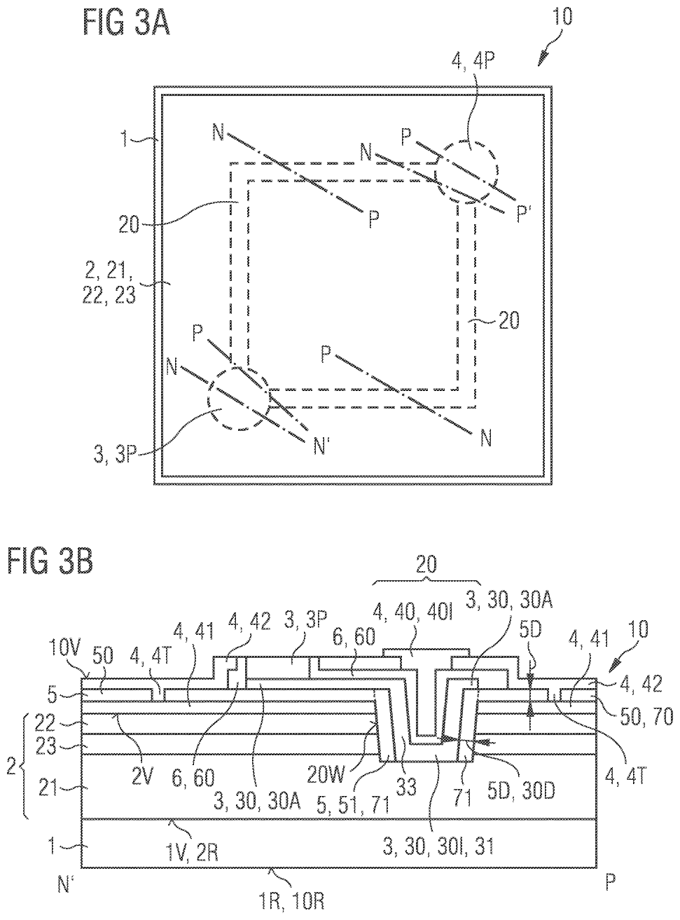

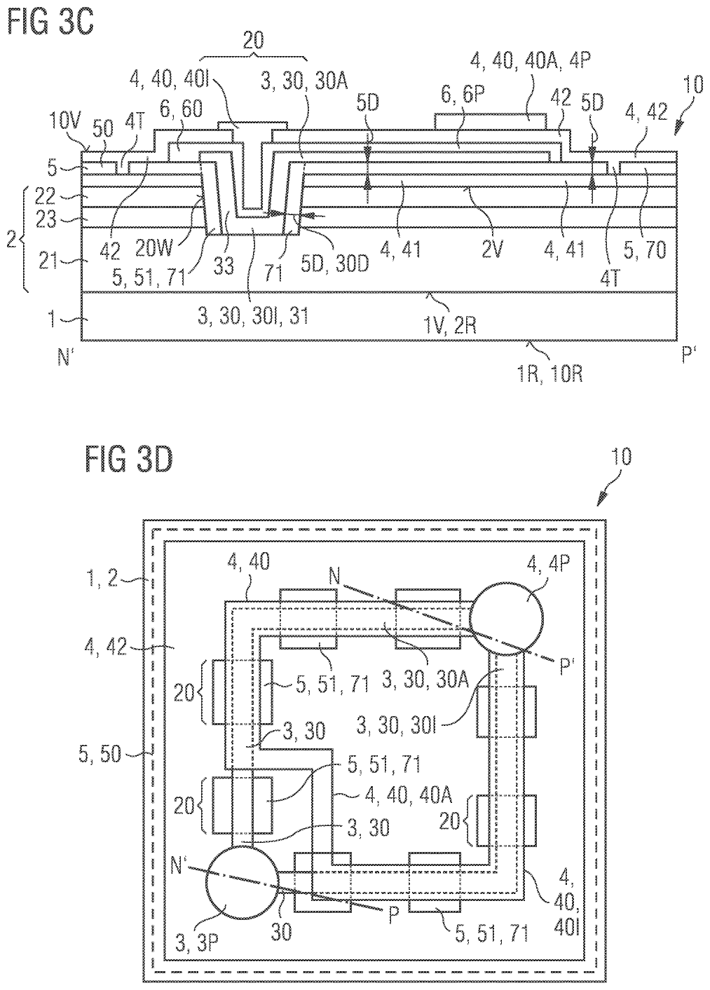

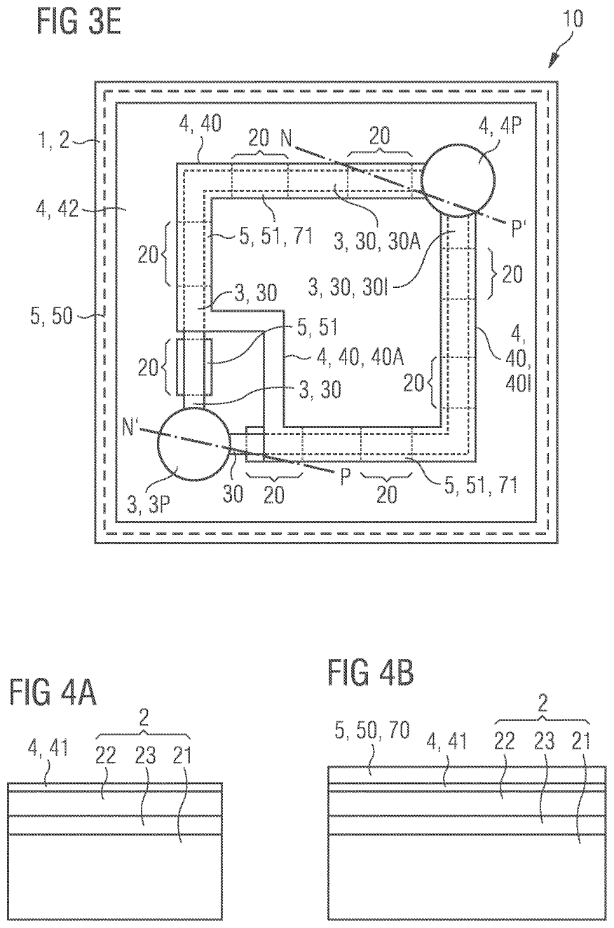

The exemplary embodiment shown in FIG. 3A is substantially the same as the exemplary embodiment of a component 10 shown in FIG. 2A. Unlike FIG. 2A, where a continuous opening 20 extends in top view for instance from the first connection pad 3P to the second connection pad 4P, in FIG. 3A, this contiguous opening 20 is divided into a plurality of laterally spaced openings 20.

FIGS. 3B and 3C show sections of the component 10 along the sectional planes N′P and NP′ shown in FIG. 3A, respectively, in vertical sectional view. FIG. 3B is substantially a combination of FIGS. 2B and 2C, while FIG. 3C is substantially a combination of FIGS. 2B and 2E.

FIGS. 3B and 3C illustrate in greater detail the path of the first distribution track 30 inside and outside the opening 20. Except for the regions to the first connection pad 3P and for the electrically contacting the first semiconductor layer 21 inside the opening/s 20, the first distribution track 30 may be encapsulated, in particular completely encapsulated, by the insulation layer 5 and by the separation layer 6. In top view, the semiconductor body 2 and the first distribution track 30 and/or the second distribution track 40 may have overlapping regions inside the opening/s 20, where the active zone 23 is removed and overlapping regions outside the opening/s 20, where the active zone 23 is present. Furthermore, it is shown that the first distribution track 30 is at a lower vertical level within the opening/s 20 than outside the opening/s.

The exemplary embodiment shown in FIG. 3D is substantially the same as the exemplary embodiment of a component 10 shown in FIG. 3A, except that in FIG. 3D, the connection pads 3P and 4P as well as the distribution tracks 30 and 40 comprising the inner subregions 30I and 40I and the outer subregions 30A and 40A are explicitly shown. The first distribution track 30 and the second distribution track 40 overlap in top view, are arranged one above the other, and extend parallel to each other in places. The first distribution track 30 and the second distribution track 40 may each form a frame-like distribution structure in top view.

The exemplary embodiment shown in FIG. 3E is substantially the same as the exemplary embodiment of a component 10 shown in FIG. 3D, except that the opening 20 or the plurality of openings 20 is completely covered in top view, in particular by the associated distribution track/s 30 or 40.

According to FIG. 3D, the opening/s 20 or the plurality of openings 20 in top view may each have a lateral width that is larger than a lateral width of the first and/or the second distribution track 30 or 40. The lateral width of the opening/s 20 or of the distribution track 30 or 40 is in particular a lateral extent of the opening/s 20 or of the distribution track 30 or 40 that is directed perpendicular to the longitudinal axis of the distribution track 30 or 40. In contrast, according to FIG. 3E, the lateral width of the opening/s 20 is at most equal to or smaller than the lateral width of the associated first and/or second distribution track 30 or 40.

In particular, the exemplary embodiments of a component 10 shown in FIGS. 2A to 2E and 3A to 3E are further developments of the comparative example of a component 10 shown in FIGS. 1A to 1D. Therefore, the features disclosed in connection with the description of FIGS. 1A to 1D may be used for the embodiments shown in FIGS. 2A to 2E and 3A to 3E as long as these features do not conflict with the exemplary embodiments shown in FIGS. 2A to 2E and 3A to 3E.

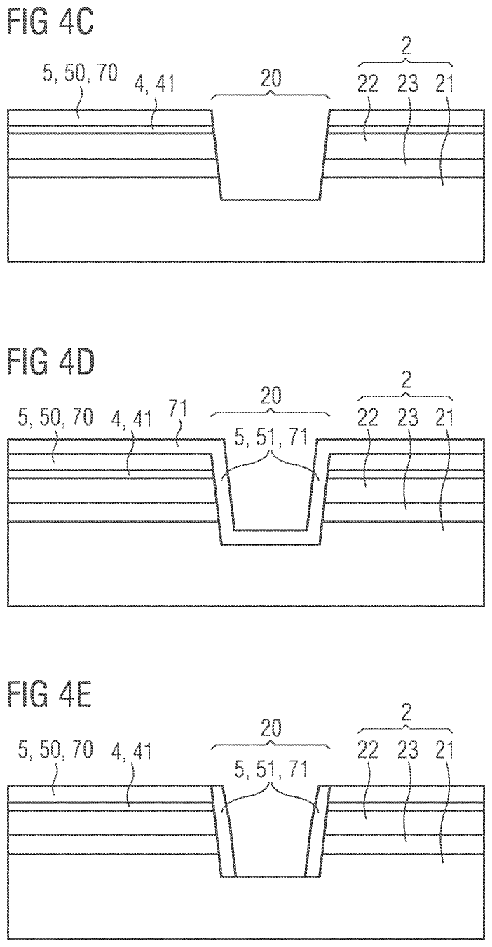

FIGS. 4A to 4E show schematic illustrations of some of the process steps for producing one or a plurality of components 10.

According to FIG. 4A, a semiconductor body 2 is provided. The semiconductor body 2 may be arranged on a substrate 1, in particular on a growth substrate 1. A connection layer 41 is applied to the semiconductor body 2, for example as part of a second electrode 4.

According to FIG. 4B, an insulation layer 5, in particular in the form of a first passivation layer 70, is applied to the connection layer 41.

According to FIG. 4C, an opening 20 or a plurality of openings 20 is/are formed throughout the passivation layer 70, the connection layer 41, the second semiconductor layer 22 and the active zone 23 into the first semiconductor layer 21. In top view, the passivation layer 70 and/or the connection layer 41 may initially cover the semiconductor body 2 completely and continue to completely cover the semiconductor body 2 outside the opening/s 20 after the formation of the opening/s 20.

According to FIG. 4D, a second passivation layer 71 is applied to the semiconductor body 2 such that the second passivation layer 71 completely covers the opening/s 20 or the semiconductor body 2 in top view. The second passivation layer 71 may initially cover the first passivation layer 70, the bottom surface and/or the side walls of the opening/s 20 completely.

According to FIG. 4E, the second passivation layer 71 is removed in places to expose the bottom surface of the respective opening 20, wherein the remaining second passivation layer 71 on the side walls of the opening/s 20 form the subregion 51 of the insulation layer 5 inside the opening 20. Outside the opening/s 20, the second passivation layer 71 may be completely removed, as a result of which the first passivation layer 70 is exposed. In a non-limiting embodiment, the second passivation layer 71 is removed in places by an anisotropic etching process and/or by a maskless etching process. It is possible that the first passivation layer 70 is partially removed and thus thinned in the process. In this sense, the first passivation layer 70 may act as a sacrificial layer during the partial removal of the second passivation layer 71. In particular, the exposed or thinned first passivation layer 70 forms the main region 50 of the insulation layer 5 outside the opening/s 20.

The second passivation layer 71 remaining on the side walls of the opening/s 20 serves, in particular, as a spacer within the opening/s 20 in the further process steps, for example, for forming the first distribution track 30 or the through-via 33 of the first electrode 3. The first passivation layer 70 and the second passivation layer 71 can be formed from the same material, for example from SiO2 or from different electrically insulating materials.

Using the process steps shown in FIGS. 4A to 4E, an electrically conductive connection layer 41 of the second electrode 4, in particular one that is transmissive to radiation, can thus be applied two-dimensionally to the second semiconductor layer 22 prior to formation of the main region 50 of the insulation layer 5, wherein the main region 50 is subsequently formed by applying the first passivation layer 70 onto the connection layer 41. After forming the opening/s 20, the subregion 51 is formed by applying the second passivation layer 71 over the entire surface of the main region 50 and the opening/s 20, in particular without a separate photographic technique. In this case, the second passivation layer 71 can initially cover the first main region 50 and the side walls 20W as well as a bottom surface of the opening 20 completely, wherein the second passivation layer 71 is subsequently removed in places, in particular also without additional photographic technique. In particular, the remaining second passivation layer 71 forms the subregion 51 of the insulation layer 5 on the side walls 20W. In this sense, the subregion 51 of the insulation layer 5 can be formed in a self-aligned manner on the side walls 20W of the opening 20, wherein the subregion 51 is parallel or conformal to the side walls 20W. A lateral distance 30D between the first distribution track 30 and the semiconductor body 2 or between the through-via 33 and the semiconductor body 2 can thus be minimized, and is for instance given by the single layer thickness of the subregion 51 within the opening 20.

This application claims the priority of the German patent application DE 10 2018 124 341.3, the disclosure content of which is hereby included by reference.

The invention is not restricted to the exemplary embodiments by the description of the invention made with reference to the exemplary embodiments. The invention rather comprises any novel feature and any combination of features, including in particular any combination of features in the claims, even if this feature or this combination is not itself explicitly indicated in the patent claims or exemplary embodiments.

### LIST OF REFERENCE SIGNS

10 Component
10V Front side of the component
10R Rear side of the component
1 Substrate
1V Front side of the substrate
1R Rear side of the substrate
2 Semiconductor body
2V Front-side main surface of the semiconductor body
2R Rear-side main surface of the semiconductor body
20 Opening of the semiconductor body
20W Sidewall of the opening of the semiconductor body
21 First semiconductor layer
22 Second semiconductor layer
23 Active zone
3 First electrode
30 Distribution track of the first electrode
31 Connection layer of the first electrode
33 Through-via of the first electrode
30A Outer subregion of the first distribution track
30D Distance between distribution track and semiconductor body or between through-via plating and semiconductor body
30I Inner subregion of the first distribution track
3P Connection pad of the first electrode
3T Through-contact of the first electrode
4 Second electrode
40 Distribution track of the second electrode
40A Outer subregion of the second distribution track
40I Inner subregion of the second distribution track
41 Connection layer of the second electrode
42 Contact layer of the second electrode
4P Connection pad of the second electrode
4T Through-contact of the second electrode
5 Insulation layer
50 Main region of the insulation layer
51 First subregion of insulation layer/spacer
52 Second subregion of the insulation layer
53 Third subregion of the insulation layer
5D Thickness of the insulation layer
6 Separation layer
60 First sublayer of the separation layer
6P Second sublayer of the separation layer
70 First passivation layer
71 Second passivation layer

1. A component comprising a semiconductor body, a first electrode and a second electrode, wherein:
the semiconductor body comprises a first semiconductor layer, a second semiconductor layer, and an active zone arranged therebetween;
the first electrode is configured for electrically contacting the first semiconductor layer and has a first distribution track for uniformly distributing current in the first semiconductor layer;
the second electrode is configured for electrically contacting the second semiconductor layer and has a second distribution track for uniformly distributing current in the second semiconductor layer;
the first distribution track and the second distribution track are arranged at least regionally one above the other on the same side of the semiconductor body, overlap in top view, and cover the semiconductor body only in places;
the first distribution track extends in places through the second semiconductor layer and the active zone to the first semiconductor layer, the active zone being removed only in places in overlapping regions of the semiconductor body with the first distribution track; and
the semiconductor body has an opening, wherein the first distribution track and the second distribution track overlap in top view in places inside the opening and in places outside the opening;
the second electrode has a plurality of radiation non-transmissive strip-shaped second distribution tracks, a radiation non-transmissive connection pad, a radiation-transmissive connection layer and a radiation-transmissive contact layer;
the second electrode completely covers the active zone or the semiconductor body in top view;
the connection layer is directly adjacent to the second semiconductor layer;
an insulation layer is arranged in vertical direction between the contact layer and the connection layer; and
the contact layer is electrically conductively connected to the connection layer throughout the insulation layer via a plurality of through-contacts.

2. The component according to claim 1, further comprising a substrate on which the semiconductor body is grown, the first electrode and the second electrode being arranged one above the other on the same main surface of the semiconductor body facing away from the substrate.

3. The component according to claim 2, wherein the substrate is a sapphire substrate.

4. The component according to claim 1, wherein the opening extends through the second semiconductor layer and the active zone and into the semiconductor layer, wherein,
the first distribution track forms a through-via within the opening;
side walls of the opening are covered by an insulation layer; and
a lateral distance between the through-via and the semiconductor body is given exactly by a single layer thickness of the insulation layer inside the opening.

5. The component according to claim 4, wherein the side walls of the opening form an angle of 90°±30° with a main plane of extension of the active zone.

6. The component according to claim 1, wherein:
the semiconductor body has a plurality of laterally spaced openings each extending throughout the second semiconductor layer and the active zone to the first semiconductor layer;
a plurality of first distribution tracks and a plurality of second distribution tracks are formed regionally inside the openings and regionally outside the openings; and
the first distribution tracks form a first distribution structure and the second distribution tracks form a second distribution structure, wherein at least 50% of the first distribution structure is located within the second distribution structure in top view of the semiconductor body, or vice versa.

7. The component according to claim 4,
wherein the first distribution track is formed to be radiation-reflective and extends along a vertical direction from a bottom surface of the opening via the side walls as far as a surface of a main region of the insulation layer facing away from the semiconductor body outside the opening, the first distribution track projecting laterally beyond the opening in top view.

8. The component according to claim 1, wherein the semiconductor body has a plurality of laterally spaced openings each extending throughout the second semiconductor layer and the active zone to the first semiconductor layer, the first distribution track and/or the second distribution track being formed contiguously and being arranged regionally inside the openings and regionally outside the openings.

9. The component according to claim 1, wherein
the first electrode has a first freely accessible connection pad electrically conductively connected to the first distribution track;
the second electrode has a second freely accessible connection pad electrically conductively connected to the second distribution track; and
the active zone in overlapping regions of the semiconductor body with the first and/or second connection pad is at least partially not removed.

10. The component according to claim 1, wherein the first electrode comprises a plurality of strip-shaped first distribution tracks formed of a metal, the first distribution tracks covering at most 10% of a lateral main surface of the semiconductor body in top view.

11. The component according to claim 1, wherein the second electrode comprises a plurality of strip-shaped second distribution tracks formed of a metal, the second distribution tracks covering at most 10% of a lateral main surface of the semiconductor body in top view.

12. (canceled)

13. The component according to claim 1, wherein:
the active zone is configured to generate electromagnetic radiation during operation of the component;
the first electrode is opaque to the generated radiation and, in top view, only partially covers the active zone; and
the second electrode is formed to be opaque in places with respect to the generated radiation and transparent in places with respect to the generated radiation and, in top view, completely covers the active zone.

14. The component according to claim 1, wherein the first electrode comprises a plurality of radiation non-transmissive strip-shaped first distribution tracks and a radiation non-transmissive connection pad, the first electrode only partially covering the active zone or the semiconductor body in top view.

15. A method for producing a component according to claim 4, wherein the method comprises:
forming an insulation layer, in top view, from a main region outside the opening and a subregion at least partially inside the opening, the main region being directly adjacent to the subregion and being formed in a separate process step prior to the subregion.

16. The method according to claim 15, further comprising:
forming the main region by applying a first passivation layer to a radiation-transmissive electrically conductive connection layer of the second electrode prior to the formation of the opening;
forming the subregion after the formation of the opening by applying a second passivation layer to surfaces of the opening, wherein the second passivation layer runs conformally to and initially completely covers side walls and a bottom surface of the opening, and
removing the second passivation layer in places to expose the bottom surface of the opening, the remaining second passivation layer on the side walls of the opening forming the subregion of the insulation layer.

17. The method according to claim 16, wherein, for exposing the bottom surface of the opening, the second passivation layer is removed in places by an anisotropic and maskless etching process.

18. The component according to claim 9, wherein in top view, the second freely accessible connection pad overlaps with the first distribution track.

19. A component comprising:
a substrate, a semiconductor body, a first electrode and a second electrode,
wherein:
the semiconductor body comprises a first semiconductor layer, a second semiconductor layer, and an active zone arranged therebetween;
the first electrode is configured for electrically contacting the first semiconductor layer and has a first distribution track for uniformly distributing current in the first semiconductor layer;
the second electrode is configured for electrically contacting the second semiconductor layer and has a second distribution track for uniformly distributing current in the second semiconductor layer;
the first distribution track and the second distribution track are arranged at least regionally one above the other on the same side of the semiconductor body, overlap in top view, and cover the semiconductor body only in places;
the first distribution track extends in places through the second semiconductor layer and the active zone to the first semiconductor layer, the active zone being removed only in places in overlapping regions of the semiconductor body with the first distribution track;
the semiconductor body has an opening, wherein the first distribution track and the second distribution track overlap in top view in places inside the opening and in places outside the opening; and
the semiconductor body is grown on the substrate, the first electrode and the second electrode being arranged one above the other on the same main surface of the semiconductor body facing away from the substrate, the substrate being a sapphire substrate.

20. A component comprising:
a semiconductor body, a first electrode and a second electrode;
wherein:
the semiconductor body comprises a first semiconductor layer, a second semiconductor layer, and an active zone arranged therebetween;
the first electrode is configured for electrically contacting the first semiconductor layer and has a first distribution track for uniformly distributing current in the first semiconductor layer;
the second electrode is configured for electrically contacting the second semiconductor layer and has a second distribution track for uniformly distributing current in the second semiconductor layer;
the first distribution track and the second distribution track are arranged at least regionally one above the other on the same side of the semiconductor body, overlap in top view and cover the semiconductor body only in places;
the first distribution track extends in places through the second semiconductor layer and the active zone to the first semiconductor layer, the active zone being removed only in places in overlapping regions of the semiconductor body with the first distribution track;
the semiconductor body has an opening, wherein the first distribution track and the second distribution track overlap in top view in places inside the opening and in places outside the opening;
the first electrode has a first freely accessible connection pad electrically conductively connected to the first distribution track;
the second electrode has a second freely accessible connection pad electrically conductively connected to the second distribution track; and
the first freely accessible connection pad or the second freely accessible connection pad is arranged within the associated opening of the semiconductor body.
